(19) United States
(12) Patent Application Publication
(10) Pub. No.: US 2005/0042551 A1
(43) Pub. Date: Feb. 24, 2005

(54) Method of manufacturing organic electroluminescent light-emitting device

(75) Inventors: Shu-Wen Chang, Nantou County (TW); Wen-Jui Liao, Taichung County (TW)

Correspondence Address: BACON & THOMAS, PLLC, 625 SLATERS LANE, FOURTH FLOOR, ALEXANDRIA, VA, 22314, US

(73) Assignee: Wintek Corporation, TAICHUNG (TW)

(21) Appl. No.: 10/918,480

(22) Filed: Aug. 16, 2004

(30) Foreign Application Priority Data
Aug. 20, 2003 (TW) 92122937

(51) Int. Cl. G03C 5/00; B32B 9/00

(52) U.S. Cl. 430/320

(57) ABSTRACT

A method of manufacturing an organic electroluminescent light-emitting device includes the steps of forming a light-permeable anode conducting layer on a transparent substrate and then etching the light-permeable anode conducting layer to form an node pattern by means of photolithography so as to form a plurality of anode electrodes on the transparent substrate, forming crosslink insulating layers on the anode electrodes by means of photolithography, forming cathode spacers on the insulating layers respectively by means of photolithography, using a polymeric hole transporting material and a solvent to form crosslink polymeric hole transporting layers on the anode electrodes between the insulating layers by means of photolithography, depositing small-molecule electron transporting layers on the crosslink polymeric hole transporting layers respectively by means of evaporation, depositing metal cathodes on the small-molecule electron transporting layers respectively by evaporation, and then forming a packaging layer on the metal cathodes for packaging.

### BACKGROUND OF THE INVENTION

1. Field of the Invention

The present invention relates generally to a display fabrication method and more particularly, to a method of manufacturing an organic electroluminescent light-emitting device; in the method, crosslink discotic crystals are used to form a polymeric hole transporting layer on anode electrodes by photolithography, thereby enhancing the physical strength of hole transporting layers of electroluminescent elements without complicating the manufacturing process.

2. Description of the Related Art

Electroluminescent displays are popular by consumers for their advantages of lightweight, thin-thickness, shortness, minimum, and wide view angle. A conventional electroluminescent light-emitting member, as shown in FIG. 4, is comprised of a glass substrate 8, an anode conducting layer 81 disposed on the glass substrate 8, a hole transporting layer 82 overlaid on the anode conducting layer 81, an electron transporting layer 83 overlaid on the hole transporting layer 82, a cathode layer 84 disposed on the electron transporting layer 83, and an insulative packaging layer (not shown) covered on the cathode layer 84. The electroluminescent light-emitting member is electrically driven to light up.

The aforesaid electroluminescent light-emitting member can be prepared by an organic small-molecule evaporation method and a metal evaporation method. The process of small-molecule evaporation method includes the steps of etching an indium-tin-oxide (ITO) substrate by photolithography, making an insulating layer and cathode spacers on the substrate by the photolithography, depositing hole transporting layers, electron transporting layers, and metal cathodes by means of evaporation, and forming an insulative packaging layer. Copper-phthal-ocyanine (CuPc) or n-Propane-Bromide (NPB) may be used for making the small-molecule hole transporting layers. For the advantage of high softening point, CuPc is first commonly used in the industry. However, CuPc is subject to absorption of red light to affect the color when used in a full-color display panel. Other compound material, such as NPB, commonly has the disadvantage of crystallization.

Therefore, it is desirable to provide an improved method of manufacturing an organic electroluminescent light-emitting device for eliminating the drawback of low physical strength of the conventional luminescent light-emitting member made by means of organic small-molecule evaporation.

### SUMMARY OF THE INVENTION

The present invention has been accomplished under the circumstances in view. It is the main object of the present invention to provide a method of manufacturing an organic electroluminescent light-emitting device; the method greatly improves the physical strength of the electroluminescent light-emitting member. It is another object of the present invention to provide a method of manufacturing an organic electroluminescent light-emitting device; the method simplifies the process of manufacturing the organic electroluminescent light-emitting device.

To achieve the foregoing objects of the present invention, the method of manufacturing the organic electroluminescent light-emitting device is comprised of the steps of forming a light-permeable anode conducting layer on a transparent substrate and then etching the light-permeable anode conducting layer to form an node pattern by means of photolithography so as to form a plurality of anode electrodes on the transparent substrate, forming crosslink insulating layers on the anode electrodes by means of photolithography, forming cathode spacers on the insulating layers respectively by means of photolithography, using a polymeric hole transporting material and a solvent to form crosslink polymeric hole transporting layers on the anode electrodes between the insulating layers by means of photolithography, depositing small-molecule electron transporting layers on the crosslink polymeric hole transporting layers respectively by means of evaporation, depositing metal cathodes on the small-molecule electron transporting layers respectively by evaporation, and then forming a packaging layer on the metal cathodes for packaging.

Because the present invention has the polymeric hole transporting layers formed on the anode electrodes between the insulating layers by means of photolithography, the photolithography process can keep forming the insulating layers, the cathode spacers, and the polymeric hole transporting layers, thereby simplifying the process of manufacturing the organic electroluminescent light-emitting device.

### BRIEF DESCRIPTION OF THE DRAWINGS

FIG. 1 is a flow diagram of the present invention.

FIG. 2 is a side view of the present invention.

FIG. 3 is a partial perspective view of the present invention.

FIG. 4 is a schematic view of the prior art.

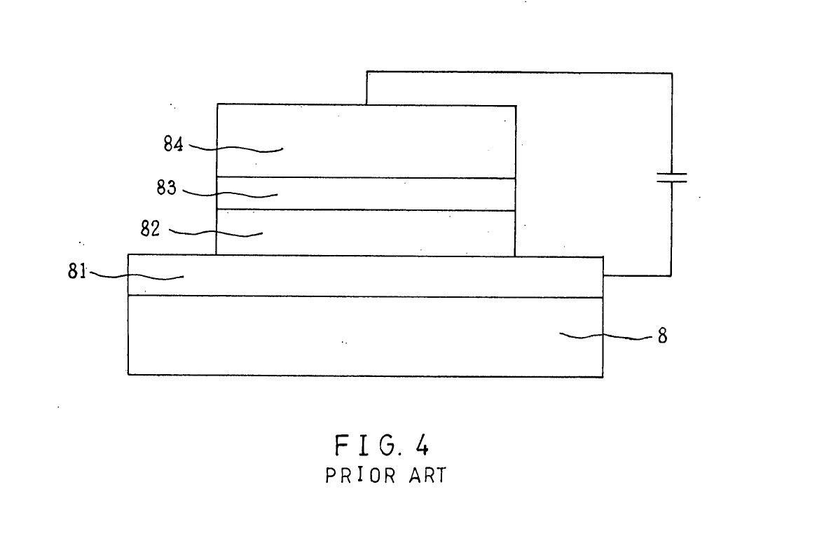

### DETAILED DESCRIPTION OF THE INVENTION

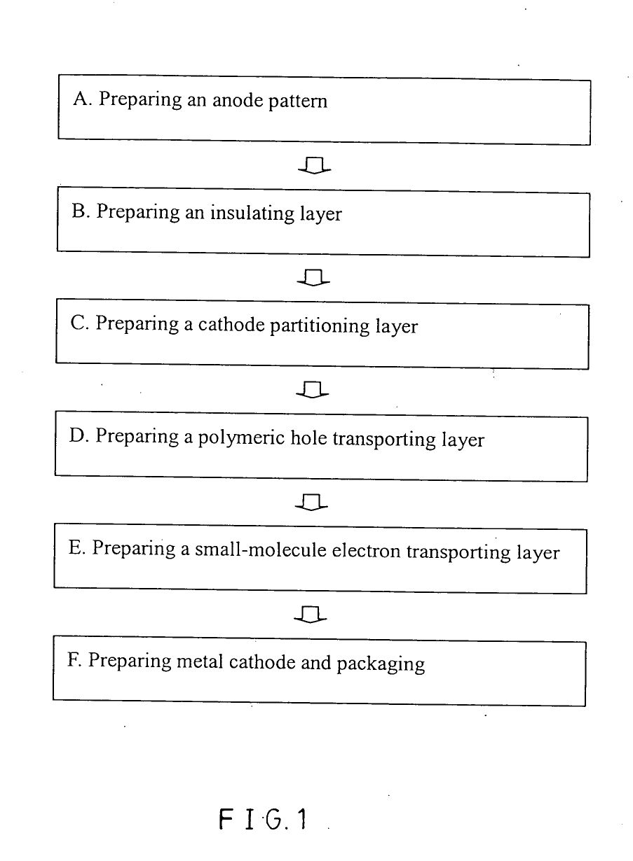

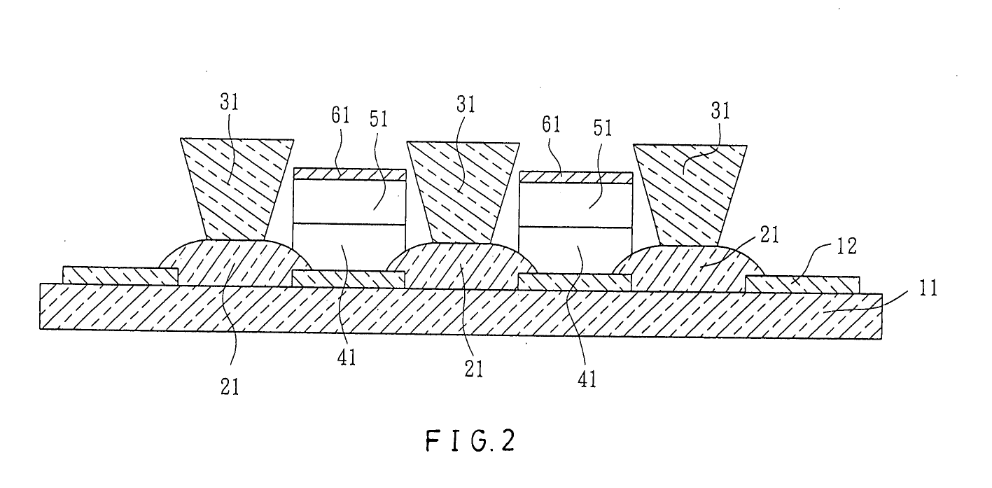

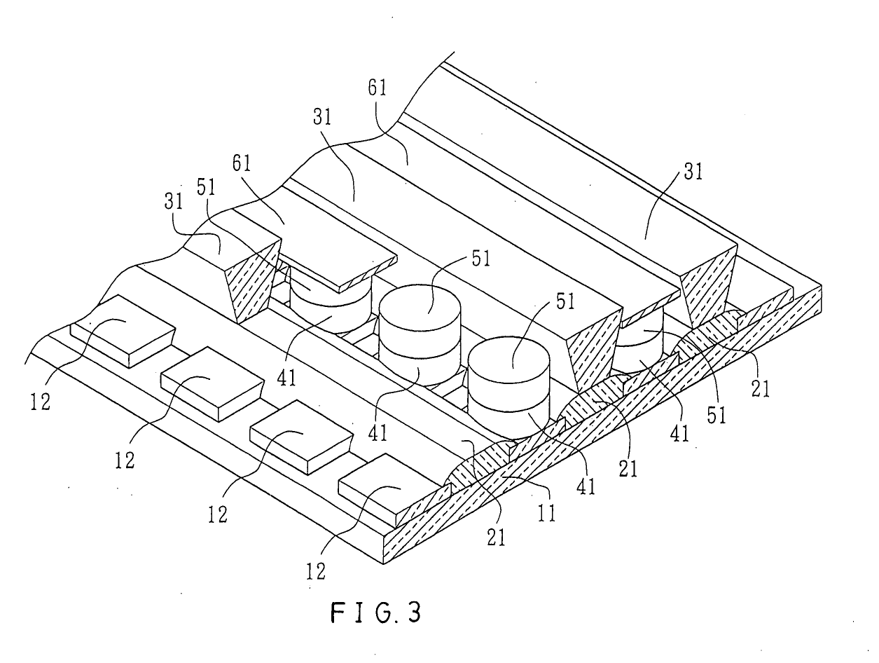

Referring to FIGS. 1-3, a method of manufacturing an organic electroluminescent light-emitting device in accordance with one embodiment of the present invention is shown comprised of the steps as follows.

A. Prepare an anode pattern 1 by forming a light-permeable anode conducting layer on a transparent substrate 11 and then etching the light-permeable anode conducting layer by means of photolithography, further forming a plurality of anode electrodes 12. In this embodiment, the light-permeable anode conducting layer is an ITO conducting layer.

B. Prepare an insulating layer 2 by forming multiple crosslink insulating layers 21 on and between the anode electrodes 12 by means of photolithography.

C. Prepare a cathode partitioning layer 3 by forming cathode spacers 31 extending upwards respectively from the insulating layers 21 by means of photolithography.

D. Prepare a polymeric hole transporting layer 4 by crosslinking a polymeric hole transporting material, which can be discotic liquid crystals, with the anode electrodes 12 to form crosslink polymeric hole transporting layers 41 respectively on the anode electrodes 12 between the insulating layers 21 by means of photolithography, in which the solvent can be tetra hydro furan or methylbenzene, under total amount of radiation 5 MJ-1 J.

E. Prepare a small-molecule electron transporting layer 5 by depositing a small-molecule electron transporting layer 51 respectively on the crosslink polymeric hole transporting layers 41 by means of evaporation.

F. Prepare metal cathode and packaging 6 by depositing metal cathodes 61 respectively on the small-molecule electron transporting layers 51 by evaporation and then forming a packaging layer (not shown) on the metal cathodes 61 for packaging. The metal cathodes 61 extend in same direction as the cathode spacers 31 to cross the anode electrodes 12.

As indicated above, the manufacturing method of the present invention is to form an ITO anode conducting layer on a transparent substrate 11 and then to form multiple anode electrodes 12 on the ITO anode conducting layer, and then to form crosslink insulating layers 21 on the anode electrodes 12 and cathode spacers 31 on the insulating layers 21 and crosslink polymeric hole transporting layers 41 of discotic liquid crystals on the anode electrodes 12 between the insulating layers 21 by means of photolithography respectively, and then to deposit small-molecule electron transporting layers 51 on the crosslink polymeric hole transporting layers 41 and metal cathodes 61 on the small-molecule electron transporting layers 51 by means of evaporation, and finally to form a packaging layer on the metal cathodes 61 for packaging.

Because the discotic liquid crystals are used for the polymeric hole transporting layers 41, the physical strength of the crosslink polymeric hole transporting layers 41 is superior to the small-molecule electron transporting layer 5. When crosslink, the polymeric does not solve in the solvent or cleaning solution, having a high physical strength. Using polymeric hole transporting layers instead of conventional small-molecule hole transporting layers greatly improve the molecular physical strength of the hole transporting layers of the electroluminescent light-emitting member, thereby eliminating the drawback of insufficient physical strength of the conventional designs.

Further, unlike the prior art of depositing hole transporting layers by means of evaporation, the present invention has the polymeric hole transporting layers 41 formed on the anode electrodes 12 between the insulating layers 21 by means of photolithography. Therefore, the photolithography process can keep forming the insulating layers 21, the cathode spacers 31, and the polymeric hole transporting layers 41, thereby simplifying the process of manufacturing the organic electroluminescent light-emitting device.

1. A method of manufacturing an organic electroluminescent light-emitting device comprising:
(a) forming a light-permeable anode conducting layer on a transparent substrate and then etching said light-permeable anode conducting layer to produce an anode pattern by means of photolithography so as to form a plurality of anode electrodes on said transparent substrate;
(b) forming an insulating layer on said anode electrodes by means of photolithography so as to form a plurality of crosslink insulating layers on and between said anode electrodes;
(c) forming a cathode partitioning layer on said insulating layer by means of photolithography to form a plurality of cathode spacers extending upwardly on said crosslink insulating layers;
(d) forming a polymeric hole transporting layer by crosslinking said anode electrodes with a polymeric hole transporting material by means of photolithography;
(e) depositing a small-molecule electron transporting layer on said polymeric hole transporting layer by means of evaporation;
(f) depositing metal cathodes on said small-molecule electron transporting layers respectively by evaporation and then forming a packaging layer on said metal cathodes for packaging.

2. The method as defined in claim 1, wherein said polymeric hole transporting material at the step (d) is discotic liquid crystals crosslinked with said anode electrodes.

3. The method as defined in claim 1, wherein the photolithography at the step (d) comprises total amount of radiation of within 5 MJ-1 J during the formation of said polymeric hole transporting layer.

4. The method as defined in claim 1, wherein said photolithography at the step (d) comprises a solvent of tetra hydro furan or methylbenzene.

5. The method as defined in claim 1, wherein said anode conducting layer at the step (a) is an indium-tin-oxide (ITO) conducting layer.

6. The method as defined in claim 1, wherein said metal cathodes at the step (f) extend in same direction as said cathode spacers to cross said anode electrodes.
